(19) United States
(12) Patent Application Publication
(10) Pub. No.: US 2016/0058102 A1
(43) Pub. Date: Mar. 3, 2016

(54) LUMINOUS SHOE

(71) Applicant: TERRY ELECTRONCS (S.Z) CO., LTD., Shenzhen (CN)

(72) Inventor: John GOU, Shenzhen (CN)

(21) Appl. No.: 14/510,182

(22) Filed: Oct. 9, 2014

Related U.S. Application Data
(63) Continuation of application No. 14/468,467, filed on Aug. 26, 2014.

(51) Int. Cl. A43B 3/00; F21L 4/08; F21V 23/04; H05K 1/18; F21V 33/00

(52) U.S. Cl. CPC A43B 3/001; H05K 1/189; F21V 33/0008; F21V 23/0414; F21L 4/08; F21V 23/0485; F21W 2121/06

(57) ABSTRACT

A luminous shoe of the disclosure includes a sole and a light-emitting device located at the sole. The light-emitting device includes a control box and a light belt exposed out of the control box and electrically connected with the control box. The light belt includes a housing, a flex printed circuit (FPC) received in the housing, a plurality of luminous elements located on the FPC and electrically connected with the FPC, and a supporting member received in the housing. The supporting member supports the FPC to fix the FPC in the housing, and ensures uniformity of the flashing direction of the luminous elements.

### CROSS REFERENCE TO RELATED APPLICATIONS

This application is a divisional application of U.S. patent application Ser. No. 14/468,467, entitled “LUMINOUS SHOE” filed on Aug. 26, 2014. The above listed application is hereby incorporated by reference herein as if set forth in its entirety.

### BACKGROUND

1. Technical Field

The present disclosure generally relates to shoes, and especially to a luminous shoe.

2. Description of Related Art

Luminous shoes are popular with children and young people due to the fashion appearance and safety of the luminous shoes. When people wear the luminous shoes, the luminous shoes generally emit lights with various colors to highlight the personalization and the fashion of the shoes.

The luminous shoe generally includes a light-emitting device mounted on a sole of the shoe. The light-emitting device includes a light belt and a control box driving the light belt to emit light. In the prior arts, the light belt generally includes a FPC (flex printed circuit) and a transparent protection housing. A plurality of luminous elements are located on the FPC. The transparent protection housing receives the FPC to protect the luminous elements. Because it is easy for the FPC in the transparent protection housing to be deformed, due to gaps between the FPC and the interior walls of the transparent protection housing and the flexibility of the FPC, the luminous elements on the FPC are prone to be out of order. As a result, flashing directions of the luminous elements are incongruous, which influences the lighting effect and the overall visual impression of the luminous shoe.

Therefore, a need exists in the industry to overcome the described problems.

### SUMMARY

The purpose of the disclosure is to solve the problem that flashing directions of luminous elements on a light belt of a luminous shoe are incongruous.

In order to solve the problem, the disclosure offers technical proposal as follow.

A luminous shoe of the disclosure includes a sole and a light-emitting device located at the sole. The light-emitting device includes a control box and a light belt exposed out of the control box and electrically connected with the control box. The light belt includes a housing, a flex printed circuit (FPC) received in the housing, a plurality of luminous elements located on the FPC and electrically connected with the FPC, and a supporting member received in the housing. The supporting member supports the FPC to fix the FPC in the housing.

A control PCB (printed circuit board) is received in the control box. The light-emitting device further includes a rechargeable battery located at the control PCB and electrically connected with the control PCB, and a battery charging interface exposed out of the control box and electrically connected with the control PCB. The rechargeable battery supplies power for the light-emitting device, and is charged with electricity by the way of a connection between the battery charging interface and an external power source.

The light-emitting device further includes a battery status indicator located in the control box, and electrically connected with the control PCB and the rechargeable battery. The battery status indicator indicates the charging status of the rechargeable battery.

The supporting member is made of PVC (Polyvinyl chloride polymer).

The light-emitting device further includes a manual button switch exposed out of the control box and electrically connected with the control PCB. The manual button switch controls the light belt to turn on, to turn off, and the changes of light-emitting modes of the light belt.

Under a standby mode of the light belt, if a pressing span of the manual button switch is greater than a first predetermined time, the control PCB drives the light belt to open, and the light belt works according to a predetermined light-emitting mode. Under a light-emitting state of the light belt, per the manual button switch is pressed once, and the pressing span of the manual button switch is less than a second predetermined time, the control PCB controls the light belt to change the light-emitting modes. Under the light-emitting state of the light belt, if the pressing span of the manual button switch is greater than the first predetermined time, the control PCB controls the light belt to close. The first predetermined time is greater than the second predetermined time.

The light-emitting device further includes a sense-finding vibration switch located in the control box and electrically connected with the control PCB. The sense-finding vibration switch controls the light belt to turn on, to turn off, and the change of light-emitting modes of the light belt.

Under a standby mode of the light belt, if the sense-finding vibration switch is triggered a first predetermined times during a third predetermined time, the control PCB drives the light belt to open, and the light belt works according to a predetermined light-emitting mode. Under a light-emitting state of the light belt, per the sense-finding vibration switch is triggered once during the third predetermined time, the control PCB controls the light belt to change the light-emitting modes. Under the light-emitting state of the light belt, if the sense-finding vibration switch is triggered a second predetermined times during the third predetermined time, the control PCB controls the light belt to close. Each of the first predetermined times and the second predetermined times is greater than or equal to 2 times.

The light-emitting device further includes an omnidirectional vibration switch located in the control box and electrically connected with the control PCB. Under a light-emitting state of the light belt, if the omnidirectional vibration switch is triggered, the control PCB controls the light belt to change the light-emitting modes of the light belt.

It follows that the FPC of the light belt of the luminous shoe of the disclosure is fixed in the housing of the light belt by support of the supporting member in the housing. As a result, the luminous elements located on the FPC are arranged in order, due to fixation of the FPC, which ensures uniformity of the flashing direction of the luminous elements. Therefore, when the luminous shoe is lighting, the overall visual impression and the beauty of the luminous shoe are improved.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded view of a luminous shoe of the disclosure.

FIG. 2 is a schematic perspective view of a light-emitting device of FIG. 1 according to a first exemplary embodiment of the disclosure.

FIG. 3 is a cross-sectional view along line III-III of FIG. 2 according to an exemplary embodiment of a light belt of the disclosure.

FIG. 4 is a cross-sectional view along line III-III of FIG. 2 according to another second exemplary embodiment of the light belt of the disclosure.

FIG. 5 is a schematic perspective view of the light-emitting device of FIG. 1 according to a second exemplary embodiment of the disclosure.

### DETAILED DESCRIPTION

The disclosure is illustrated by way of example and not by way of limitation in the figures of the accompanying drawings, in which like reference numerals indicate similar elements. It should be noted that references to “an” or “one” embodiment in this disclosure are not necessarily to the same embodiment, and such references can mean “at least one” embodiment.

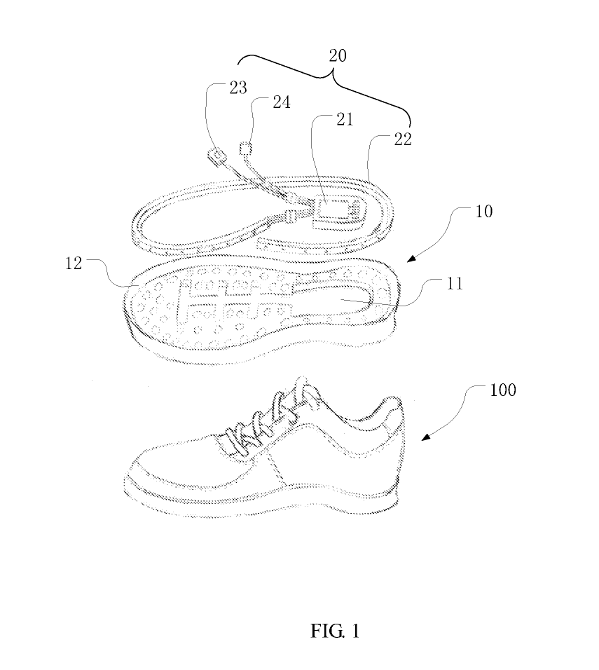

With reference to FIG. 1, a luminous shoe 100 includes a sole 10 and a light-emitting device 20 located at the sole 10. The light-emitting device 20 includes a control box 21 and a light belt 22 exposed out of the control box 21 and electrically connected with the control box 21.

In the embodiment, the sole 10 defines a receiving slot 11 at the bottom of the sole 10, and defines a mounting groove 12 on sides of the sole 10. The mounting groove 12 extends around a circumferential direction of the sole 10. In assembly, the control box 21 is received in the receiving slot 11, and is fixed with the sole 10 by a fixing cover (not shown). The light belt 22 is received in the mounting groove 12, and is configured around the sides of the sole 10.

Alternatively, the light belt 22 may be configured on other positions of the luminous shoe 100 according to appearance requirements of the luminous shoe 100, such as a shoe upper of the luminous shoe 100.

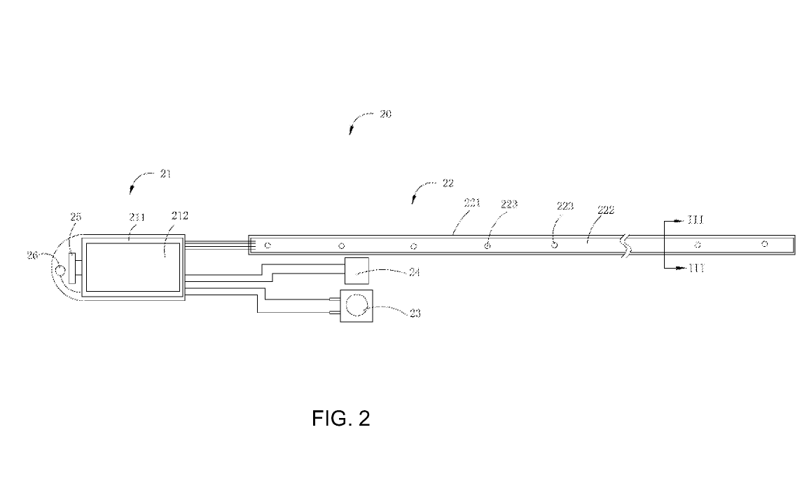

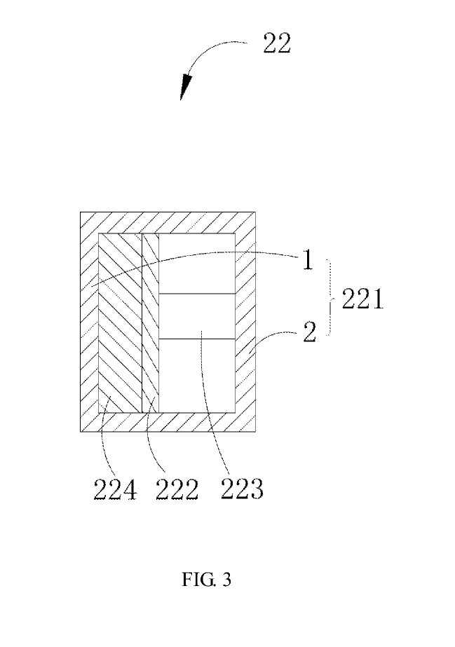

With reference to FIG. 2 and FIG. 3, the light belt 22 includes a housing 221, a FPC (flex printed circuit) 222 received in the housing 221, and a supporting member 224 received in the housing 221. A plurality of luminous elements 223 are located on the FPC 222. The control box 21 drives the luminous elements 223 to emit light, so that the luminous shoe 100 emits lights with various colors. The supporting member 224 supports the FPC 222 to fix the FPC 222 with the housing 221.

It follows that, the FPC 222 of the disclosure is fixed in the housing 221 of the light belt 22 by support of the supporting member 224 in the housing 221. As a result, the luminous elements 223 located on the FPC 222 are arranged in order, due to fixation of the FPC 222 in the housing 221, which ensures uniformity of the flashing direction of the luminous elements 223. Therefore, when the luminous shoe 100 is lighting, the overall visual impression and the beauty of the luminous shoe 100 are improved.

With reference to FIG. 3, in the embodiment, the housing 221 includes a first sidewall 1 and a second sidewall 2 opposite to the first sidewall 1. In assembly, the supporting member 224 resists between a bottom of the FPC 222 and the first sidewall 1, and the luminous elements 223 resists the second sidewall 2. As a result, the luminous elements 223 are fixed in the housing 221, and always keep in order. When the light-emitting device 20 shakes under an external force, because the FPC 222 is fixed in the housing 221 due to the support of the supporting member 224, it is not easy for the FPC 222 to deform, which ensures the uniformity of the flashing direction of the luminous elements 223.

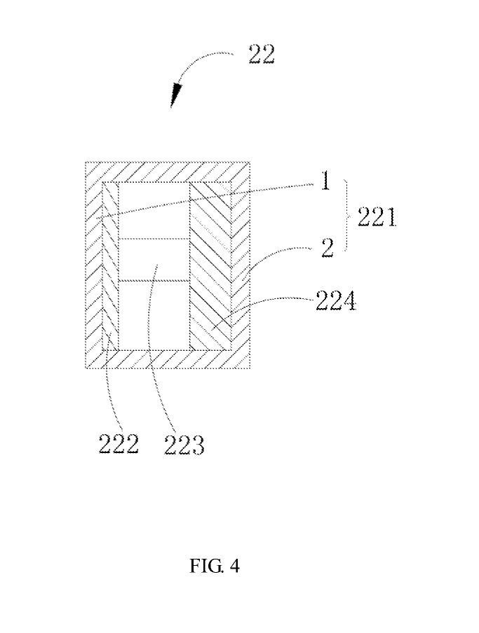

With reference to FIG. 4, alternatively, the supporting member 224 may be configured between the luminous elements 223 and the second sidewall 2 of the housing 221, and the bottom of the FPC 22 resists the first sidewall 1 of the housing 221.

In the embodiment, each of the luminous elements 223 is a LED. The LED is fixed on the FPC 222 by a SMT (surface mounting technology) process, and is electrically connected with the FPC 222.

In the embodiment, the supporting member 224 is made of transparent PVC (polyvinyl chloride polymer).

In the embodiment, a control PCB (printed circuit board) 211 is located in the control box 21. The light-emitting device 20 further includes a rechargeable battery 212 and a charging interface 24. The rechargeable battery 212 is located on the control PCB 211, and is electrically connected with the control PCB 211. The rechargeable battery 212 is configured to supply power for the light-emitting device 20. The charging interface 24 exposes out of the control box 21 and electrically connected with the control PCB 211. The rechargeable battery 212 is charged with electricity by the way of the connection between the battery charging interface 24 and an external power source.

It follows that, when the battery power of the rechargeable battery 212 is low, the rechargeable battery 212 is charged with electricity by the connection between the battery charging interface 24 and the external power source. As a result, the lighting function of the luminous shoe 100 is available continually. When the battery power of the rechargeable battery 212 is low, it is not necessary for consumers to worry about invalidity of the lighting function of the luminous shoe 100. Therefore, the rechargeable battery 212 of the luminous shoe 100 of the disclosure ensures stability and persistence the lighting function of the luminous shoe 100, which improves purchase intention of the consumers.

In the embodiment, the light-emitting device 20 further includes a battery status indicator 26 located in the control box 21 and electrically connected with the control PCB 211 and the rechargeable battery 212. The battery status indicator 26 is positioned so as to indicate the charging status of the rechargeable battery 212. In detail, when the rechargeable battery 212 is charged with electricity and the battery power of the rechargeable battery 212 is not full, the battery status indicator 26 flashes continuously. When the battery charging for the rechargeable battery 212 is finished, the battery status indicator 26 constant lights to remind the consumers to pull out the external power source.

With reference to FIG. 2, in a first exemplary embodiment, the light-emitting device 20 further includes a manual button switch 23 electrically connected with the control PCB 211, and is configured to control the light belt 22 to turn on, to turn off, and the change of light-emitting modes of the light belt 22.

In the first exemplary embodiment, the manual button switch 23 exposes out of the control box 21 and is positioned on the shoe upper of the luminous shoe 100.

When the control PCB 211 is connected to the rechargeable battery 212, the light belt 22 is in a standby mode. Under the standby mode of the light belt 22, if a pressing span of the manual button switch 23 is greater than a first predetermined time T1, the control PCB 211 drives the light belt 22 to open, and the light belt 22 works according to a predetermined light-emitting mode of the light belt 22.

Under the light-emitting state of the light belt 22, per the manual button switch 23 is pressed once, and the pressing span of the manual button switch 23 is less than a second predetermined time T2, the control PCB 211 controls the light belt 22 to change light-emitting modes of the light belt 22.

Under the light-emitting state of the light belt 22, and if the pressing span of the manual button switch 23 is greater than the first predetermined time T1, the control PCB 211 controls the light belt 22 to close. In the embodiment, the first predetermined time T1 is greater than the second predetermined time T2.

For example, the first predetermined time T1 is supposed to be 1 second, and the second predetermined time T2 is supposed to be 0.5 second, that is T1=1 s, T2=0.5 s. When the control PCB 211 is connected to the rechargeable battery 212, the light belt 22 is in the standby mode. Under the standby mode of the light belt 22, if the pressing span of the manual button switch 23 is greater than 1 second, such as 2 seconds, the control PCB 211 drives the light belt 22 to open, and the light belt 22 works according to the predetermined light-emitting mode.

Under the light-emitting state of the light belt 22, per the manual button switch 23 is pressed once, and the pressing span of the manual button switch 23 is less than 0.5 second, such as 0.2 second, the conduction of the manual button switch 23 is instantaneous, and the control PCB 211 controls the light belt 22 to change the light-emitting modes of the light belt 22.

Under the light-emitting state of the light belt 22, if the pressing span of the manual button switch 23 is greater than 1 second, such as 1.5 second, the control PCB 211 controls the light belt 22 to close. That is, under the light-emitting state of the light belt 22, as long as the pressing span of the manual button switch 23 is greater than 1 second, the light belt 22 is closed at any time.

In the embodiment, the light-emitting modes of the light belt 22 includes changes of the light color of the luminous elements 223 of the light belt 22, changes of light order of the luminous elements 223 of the light belt 22, and flashing order changes of the luminous elements 223 of the light belt 22, and so on. Of course, the light-emitting modes of the light belt 22 may be set up according to requirements and fancy of the consumers.

Alternatively, the first predetermined time T1 and the second predetermined time T2 may be set up according to the light requirements of the luminous shoe 100.

It follows that, it only takes the manual button switch 23, the light belt 22 can be opened, closed, and carries out change of the light-emitting modes of the light belt 22. As a result, the quantity of the electrical components of the luminous shoe 100 is reduced, and operation for the light belt 22 is simple, which results of low cost and friendliness to consumers.

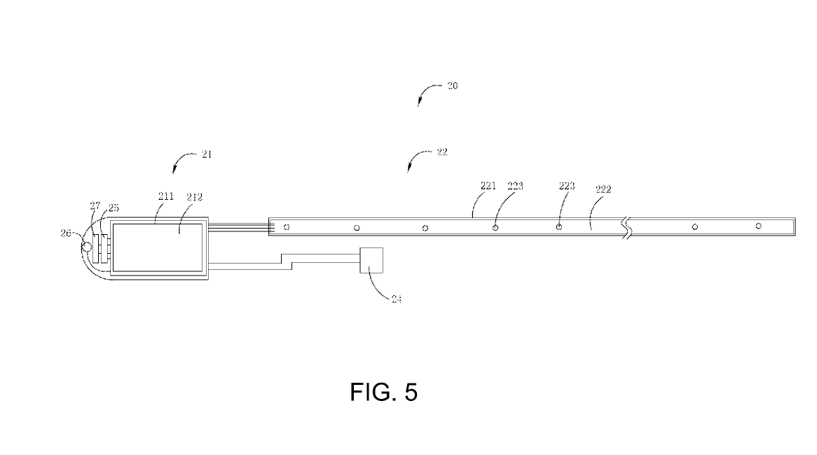

With reference to FIG. 5, in a second exemplary embodiment, the light-emitting device 20 further includes a sense-finding vibration switch 27 located in the control box 21 and electrically connected with the control PCB 211. The sense-finding vibration switch 27 controls the light belt 22 to turn on, to turn off, and the change of the light-emitting modes of the light belt 22.

In detail, when the control PCB 211 is connected to the rechargeable battery 212, the light belt 22 is in the standby mode. Under the standby mode of the light belt 22, if the sense-finding vibration switch 27 is triggered a first predetermined times X1 during a third predetermined time T3, the control PCB 211 drives the light belt 22 to open. Subsequently, the light belt 22 works according to the predetermined light-emitting mode.

Under the light-emitting state of the light belt 22, per the sense-finding vibration switch 27 is triggered once during the third predetermined time T3, the control PCB 211 controls the light belt 22 to change the light-emitting modes of the light belt 22.

Under the light-emitting state of the light belt 22, and if the sense-finding vibration switch 27 is triggered a second predetermined times X2 during the third predetermined time T3, the control PCB 211 controls the light belt 22 to close. In the embodiment, each of the first predetermined times X1 and the second predetermined times X2 is greater than or equal to 2 times. That is, X1≧2, X2≧2.

For example, the third predetermined time T3 is supposed to be 3 seconds, that is T3=3 s, the first predetermined times X1 is supposed to be three times, and the second predetermined times X2 is supposed to be four times, that is X1=3, X2=4.

In other words, if the consumers wearing the luminous shoe 100 wants to open the light belt 22, the consumers are required to shake the luminous shoe 100 three times during 3 seconds towards a trigger direction of the sense-finding vibration switch 27.

Under the light-emitting status of light belt 22, if the consumers shake the luminous shoe 100 once during 3 seconds towards the trigger direction of the sense-finding vibration switch 27, the light belt 22 changes the light-emitting modes of the light belt 22. Under the light-emitting status of the light belt 22, if the consumers want to close the light belt 22, the consumers are required to shake the luminous shoe 100 four times during 3 seconds towards the trigger direction of the sense-finding vibration switch 27.

Alternatively, the third predetermined time T3 and the first predetermined times X1 and the second predetermined times X2 may be set up according to actual requirements of the consumers.

In the two exemplary embodiments described above, the manual button switch 23 and the direction vibration 27 are used singly. Of course, the manual button switch 23 and the direction vibration 27 may be used in combination. That is, both of the manual button switch 23 and the direction vibration 27 are mounted in the luminous shoe 100. The consumers may selects at least one of the manual button switch 23 and the direction vibration 27 to control the light belt 22 to open, to close and to change the light-emitting mode of the light belt 22.

The light-emitting device 20 further includes an omnidirectional vibration switch 25 located in the control box 21 and electrically connected with the control PCB 211. Under the light-emitting state of the light belt 22, if the omnidirectional vibration switch 25 is triggered, the control PCB 211 controls the light belt 22 to change the light-emitting modes of the light belt 22. In the embodiment, no matter what shaking directions of the luminous shoe 100, the omnidirectional vibration switch 25 may be triggered as long as the omnidirectional vibration switch 25 shakes.

That is, after the manual button switch 23 or the sense-finding vibration switch 27 is triggered to open the light belt 22, during walking of the consumers, as long as the omnidirectional vibration switch 27 shakes, the omnidirectional vibration switch 27 is triggered to change the light-emitting modes of the light belt 22. As a result, when the consumers want to change the light-emitting modes of the light belt 22, it is not necessary for the consumers to stoop down to operate the manual button switch 23 or shake the luminous shoe 100 towards the triggering direction of the sense-finding vibration switch 27 to trigger the sense-finding vibration switch 27, as long as the consumers walk to shake the omnidirectional vibration switch 27, the light belt 22 changes the light-emitting modes of the light belt 20, which results of convenience for the consumers and friendliness for the consumers.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A luminous shoe comprising:
a sole; and
a light-emitting device located at the sole, wherein the light-emitting device comprises:
a control box; and
a light belt exposed out of the control box and electrically connected with the control box, wherein the light belt comprises:
a housing;
a flex printed circuit (FPC) received in the housing;
a plurality of luminous elements located on the FPC and electrically connected with the FPC; and
a supporting member received in the housing, and wherein the supporting member supports the FPC to fix the FPC in the housing.

2. The luminous shoe of claim 1, wherein a control PCB (printed circuit board) is received in the control box, and the light-emitting device further comprises a rechargeable battery located at the control PCB and electrically connected with the control PCB, and a battery charging interface exposed out of the control box and electrically connected with the control PCB, and wherein the rechargeable battery supplies power for the light-emitting device, and is charged with electricity by the way of a connection between the battery charging interface and an external power source.

3. The luminous shoe of claim 2, wherein the light-emitting device further comprises a battery status indicator located in the control box, and electrically connected with the control PCB and the rechargeable battery, and the battery status indicator indicates the charging status of the rechargeable battery.

4. The luminous shoe of claim 1, wherein the supporting member is made of PVC (Polyvinyl chloride polymer).

5. The luminous shoe of claim 2, wherein the light-emitting device further comprises a manual button switch exposed out of the control box and electrically connected with the control PCB, and the manual button switch controls the light belt to turn on, to turn off, and the changes of light-emitting modes of the light belt.

6. The luminous shoe of claim 5, wherein under a standby mode of the light belt, if a pressing span of the manual button switch is greater than a first predetermined time, the control PCB drives the light belt to open, and the light belt works according to a predetermined light-emitting mode; under a light-emitting state of the light belt, per the manual button switch is pressed once, and the pressing span of the manual button switch is less than a second predetermined time, the control PCB controls the light belt to change light-emitting mode; under the light-emitting state of the light belt, if the pressing span of the manual button switch is greater than the first predetermined time, the control PCB controls the light belt to close, and wherein the first predetermined time is greater than the second predetermined time.

7. The luminous shoe of claim 2, wherein the light-emitting device further comprises a sense-finding vibration switch located in the control box and electrically connected with the control PCB, the sense-finding vibration switch controls the light belt to turn on, to turn off, and the change of light-emitting modes of the light belt.

8. The luminous shoe of claim 7, wherein under a standby mode of the light belt, if the sense-finding vibration switch is triggered a first predetermined times during a third predetermined time, the control PCB drives the light belt to open, and the light belt works according to a predetermined light-emitting mode; under a light-emitting state of the light belt, per the sense-finding vibration switch is triggered once during the third predetermined time, the control PCB controls the light belt to change light-emitting mode; under the light-emitting state of the light belt, if the sense-finding vibration switch is triggered a second predetermined times during the third predetermined time, the control PCB controls the light belt to close, and wherein each of the first predetermined times and the second predetermined times is greater than or equal to 2 times.

9. The luminous shoe of claim 5, wherein the light-emitting device further comprises an omnidirectional vibration switch located in the control box and electrically connected with the control PCB, under a light-emitting state of the light belt, if the omnidirectional vibration switch is triggered, the control PCB controls the light belt to change the light-emitting mode of the light belt.

10. The luminous shoe of claim 7, wherein the light-emitting device further comprises an omnidirectional vibration switch located in the control box and electrically connected with the control PCB, under a light-emitting state of the light belt, if the omnidirectional vibration switch is triggered, the control PCB controls the light belt to change the light-emitting mode of the light belt.
